(19) United States
(12) Patent Application Publication
(10) Pub. No.: US 2024/0178163 A1
(43) Pub. Date: May 30, 2024

(54) Slot Bow-Tie Antenna On Package

(71) Applicant: Texas Instruments Incorporated, Dallas, TX (US)

(72) Inventors: Yiqi Tang, Allen, TX (US); Rajen M. Murugan, Dallas, TX (US); Aditya Nitin Jogalekar, Dallas, TX (US)

(21) Appl. No.: 18/072,026

(22) Filed: Nov. 30, 2022

(51) Int. Cl. H01L 23/66; H01L 23/00; H01L 23/06; H01L 23/31; H01Q 5/25; H01Q 9/28; H01Q 13/10

(52) U.S. Cl. CPC H01L 23/66; H01L 23/06; H01L 23/3107; H01L 24/20; H01Q 5/25; H01Q 9/285; H01Q 13/106; H01L 2223/6677; H01L 2224/221

(57) ABSTRACT

An example semiconductor package comprises a semiconductor die having a top surface, a passivation layer over the top surface, a first metal layer on the first passivation layer, an antenna formed in the first metal layer and offset from the semiconductor die, the antenna having a slot bow-tie configuration, a transmission line formed in the first metal layer, the transmission line coupling the semiconductor die to the antenna, and an insulating material separating the first metal layer from a second metal layer, the second metal layer configured to function as a ground reflector for the antenna. The second metal layer may extend below the antenna and the semiconductor die.

### BACKGROUND

Semiconductor devices including active and/or passive components may be manufactured into round wafers sliced from elongated cylinder-shaped single crystals of semiconductor elements or compounds. The diameter of these solid-state wafers may reach up 12 inches or more. Individual semiconductor dies are typically singulated from a round wafer by sawing streets in X- and Y-directions through the wafer in order to create rectangularly shaped discrete pieces from the wafers.

Each semiconductor die includes at least one active or passive component and die pads serving to facilitate electric connections to the component(s) of the semiconductor die. Semiconductor dies include many large families of electronic components; examples include active devices such as diodes and transistors like field-effeet transistors, passive devices such as resistors and capacitors, and integrated circuits, which can include far more than a million active and passive components.

After singulation, one or more semiconductor dies are attached to a discrete supporting substrate such as a metal leadframe or a rigid multi-level substrate laminated from a plurality of metallic and insulating layers. The conductive traces of the lead frames and substrates are connected to the die pads, typically using bonding wires or metal bumps such as solder bumps.

The assembled semiconductor dies, lead frames and/or substrates may be encapsulated to form discrete robust packages, which frequently employ hardened polymeric compounds and are formed by techniques such as transfer molding. The assembly and packaging processes are performed either on an individual basis or as part of batch processes including a strip or array of semiconductor dies on a corresponding strip or array of lead frames and/or through a single loading of a mold press.

Semiconductor technology continues trends towards miniaturization, integration, and speed. Integration of antennas and functional circuitry within a common package are sometimes referred to as antenna-on-package (AOP) or antenna-in-package (AIP). Radio frequency (RF) integrated circuits can be packaged so that rather than transmitting RF signals through contacts, such as balls or pins, to an antenna module, an antenna is provided on the top surface of package itself. This is referred as an AOP configuration. The AOP device can include a number of antennas coupled to a semiconductor or integrated circuit (IC) die, such as one or more transmitter antennas and/or receiver antennas. An AIP device is a semiconductor package arrangement wherein the antenna is integrated into the package along with a semiconductor or IC die, such as an RF IC die, to provide a wireless device. In this configuration, the antenna is not a separate component placed within the wireless device but is instead directly integrated into the package along with IC die. This approach is sometimes referred to as a discrete antenna approach. Other typical AIP components include RF/millimeter (mm) wave building blocks, an analog baseband signal chain for transmitters and receivers, as well as a customer-programmable microcontroller unit (MCU) and a digital signal processor (DSP). Packages with integrated antennas may be scaled to incorporate a variety of different wireless sensing and/or transmission standards. However, advantages of packages with integrated antennas are most apparent for applications requiring relatively small antennas, such as Wi-Fi, near-field communication (NFC), and millimeter wave (mmWave) applications.

Traditionally, mmWave antennas have been designed on a printed circuit board (PCB) using substrates with advanced materials that support efficiency at high-frequencies, such as polytetrafluoroethylene based-substrates, to deliver high-accuracy sensing. Although effective, such system designs require RF expertise to design and manufacture an antenna to work alongside the sensor. Packages with integrated antennas may reduce system complexity and manufacturing costs by eliminating the need for standalone antennas. Such sensing systems may be utilized for robotics, industrial 3D sensing, and automotive applications including driver-assist and self-driving systems.

mmWave systems generally operate in the spectrum between 24 GHz-300 GHz. In different applications, mmWave systems may be utilized for data transmission, such as with cellular networks, or in radar sensing technology for detection of objects. Due to short wavelengths of mmWave signals, system components, such as antennas, may be of relatively small size.

### SUMMARY

In an arrangement, a semiconductor package comprises a semiconductor die having a top surface, a passivation layer over the top surface, a first metal layer on the first passivation layer, an antenna formed in the first metal layer and offset from the semiconductor die, the antenna having a slot bow-tie configuration, a transmission line formed in the first metal layer, the transmission line coupling the semiconductor die to the antenna, and an insulating material separating the first metal layer from a second metal layer, the second metal layer configured to function as a ground reflector for the antenna. The second metal layer extends below the antenna and the semiconductor die.

The semiconductor package may further comprise a conductive pad on the top surface of the semiconductor die, and an opening in the passivation layer to expose the conductive pad, wherein the transmission line in the first metal layer in contact with the conductive pad through the first opening.

The transmission line may be a conductor-backed coplanar waveguide. The transmission line may comprise three parallel strips in the first metal layer, wherein the three parallel strips have a ground-signal-ground configuration.

The semiconductor package may further comprise an impedance transformer formed in the first metal layer, wherein the impedance transformer is coupled between an antenna feed and the transmission line. The transmission line may have a 50Ω impedance, and the impedance transformer may have a 75Ω impedance.

The antenna may be configured to operate in a frequency band having a millimeter wavelength. The antenna may be configured in the first metal layer to provide direct air radiation.

The antenna may comprise a metal plane having two triangular openings, the openings each having a vertex positioned near an antenna feed and a base side opposite the vertex, and wherein the distance between the base sides determines a resonant frequency of the antenna.

The semiconductor package may further comprise additional layers. A first dielectric layer may cover the first metal layer, a third metal layer may cover the first dielectric layer, and a first via in the first dielectric layer may couple the first metal layer to the third metal layer. A second dielectric layer may cover the second metal layer, a fourth metal layer may cover the second dielectric layer, and a second via in the second dielectric layer may couple the second metal layer to the fourth metal layer.

The semiconductor package may further comprise a first solder mask layer above the first metal layer, and a second solder mask layer below the second metal layer.

In another arrangement, an integrated circuit (IC), comprises an embedded die structure, including an organic panel frame, including an opening, a semiconductor die positioned within the opening, and a filling material that embeds the semiconductor die in the opening of the organic panel frame. A first redistribution layer (RDL) structure is positioned above the semiconductor die and has a conductive structure electrically connected to a contact on the semiconductor die. An antenna is formed in the first RDL structure and is offset from the semiconductor die. The antenna has a slot bow-tie configuration. A second RDL structure is positioned below the semiconductor die as a ground reflector for the antenna.

The IC may further comprise a transmission line formed in the first RDL structure. The transmission line couples the semiconductor die to the antenna. The transmission line may be a waveguide in the first RDL structure. The waveguide may have three parallel strips in the first metal layer, wherein the three parallel strips have a ground-signal-ground configuration.

The second RDL structure may extend below the antenna and the semiconductor die. The antenna may be configured to operate in a frequency band having a millimeter wavelength, and the antenna may be configured in the first RDL structure to provide direct air radiation.

The IC may further comprise an impedance transformer formed in the first RDL structure, wherein the impedance transformer is coupled between an antenna feed and the transmission line. The transmission line may have a 50Ω impedance, and the impedance transformer may have a 75Ω impedance.

The IC may further comprise a first dielectric layer covering the first RDL structure, a third RDL structure covering the first dielectric layer, and a first via in the first dielectric layer, the first via coupling the first RDL structure to the third RDL structure. A second dielectric layer may cover the second RDL structure, a fourth RDL structure may cover the second RDL structure, and a second via in the second dielectric layer may couple the second RDL structure to the fourth RDL structure.

### BRIEF DESCRIPTION OF THE DRAWINGS

Having thus described the invention in general terms, reference will now be made to the accompanying drawings, wherein:

FIG. 1 illustrates a semiconductor package having a slot bow-tie antenna-on-package configuration according to one arrangement.

FIG. 2 is a detailed illustration of a transmission line structure coupled to a semiconductor die in a semiconductor package having an antenna-on-package configuration.

FIG. 3 illustrates a slot bow-tie antenna used in a system-in-package configuration according to one arrangement.

FIG. 4 is a cross section view along the length of a semiconductor package having an antenna-on-package arrangement.

FIG. 5 is a graph illustrating a return loss plot for an antenna-on-package device for a slot bow-tie antenna according to an example arrangement.

FIG. 6 is a table listing gain and efficiency measurements for a slot bow-tie antenna according to an example arrangement.

FIGS. 7A-F illustrate radiation patterns observed for an antenna-on-package device having a slot bow-tie antenna.

FIGS. 8A-N illustrate steps for fabricating a semiconductor package for an antenna-on-package device having a slot bow-tie antenna according to one arrangement.

FIG. 9 illustrates a four-layer system in package device having a slot bow-tie antenna formed according to another arrangement.

FIG. 10 is cross section view of an antenna-on-package device having a slot bow-tie antenna showing thickness of various elements.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effeet transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “redistribution layer (RDL)” is used herein. The RDL structure is a conductive structure that may be electrically connected to a semiconductor die or other components. A packaged electronic device may include elements, such as antennas, transmission lines, waveguides, and/or impedance transformers, that are formed in the RDL structure. In one example, a packaged electronic device includes a slot bow-tie antenna formed in an RDL layer. The slot bow-tie antenna is coupled to a semiconductor die circuit by a transmission line and impedance transformer that are also formed in the RDL structure.

The term “slot bow-tie antenna” is sued herein. A slot antenna consists of a metal surface, such as flat metal plate, with one or more holes cut out of the surface. When the metal plate is driven by an RF current, the slot radiates electromagnetic waves. The radiation pattern of the slot antenna is omni-directional similar to a dipole antenna. A slot bow-tie antenna, such as the ones described herein, is a slot antenna that has slots formed in the shape of a bow tie, which generally has two mirror-image triangle shapes. In some arrangements, the bow-tie shape may also be referred to as a butterfly-shaped antenna.

The term “ground reflector” is used herein. A ground reflector is a device that reflects electromagnetic waves from an antenna. The ground reflector can be a standalone device for redirecting RF energy or can be integrated as part of an antenna assembly. The ground reflector described herein serves to modify the radiation pattern of the slot bow-tie antenna and to increase gain in the direction opposite the ground plane.

The term “coplanar waveguide” is used herein. A coplanar waveguide is a type of electrical planar transmission line that can be used to convey microwave-frequency signals. Coplanar waveguide transmission lines are built into monolithic microwave integrated circuits. The coplanar waveguide consists of a single conducting track or strip on a dielectric substrate and a pair of return conducting tracks or strips, one to either side of the conducting track. All three conductors are on the same side of the substrate and, therefore, are coplanar. The return conductors are separated from the central conducting track by a small gap, which has an unvarying width along the length of the line. On the sides away from the central conductor, the return conductors can extend to an indefinite distance so that each is notionally a semi-infinite plane. In some arrangements, the coplanar waveguide is a conductor-backed coplanar waveguide, which may also be known as coplanar waveguide with ground. The conductor-backed coplanar waveguide variant has a ground plane covering the entire back-face of the substrate. The ground-plane serves as a third return conductor.

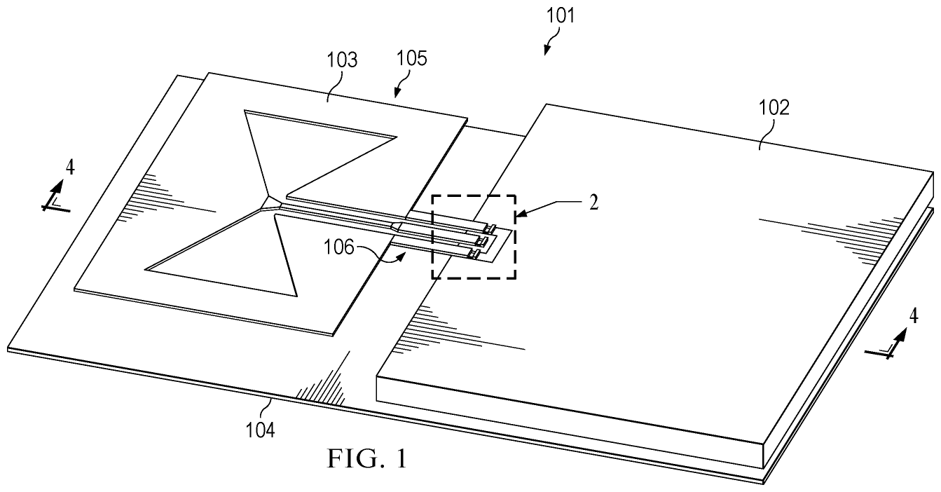

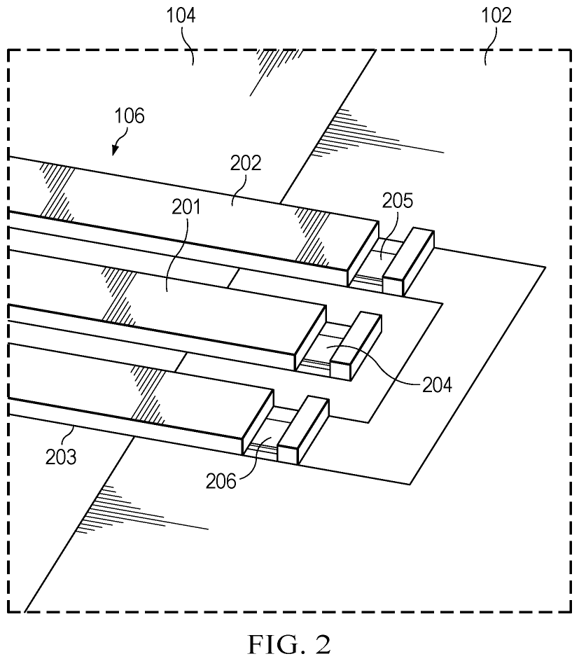

FIG. 1 illustrates a semiconductor package 101 having a slot bow-tie antenna-on-package (AOP) structure according to one arrangement. In other arrangements, this arrangement may be configured as an antenna-in-package (AIP). Semiconductor package 101 has two redistribution layers (RDL) 103, 104 in a double-sided RDL build-up structure. Semiconductor package 101 includes a semiconductor die 102 that is embedded between two conductive 103, 104. The top RDL 103 is used as the slot bow-tie antenna metal. The bottom RDL 104 is used as a ground reflector as part of an antenna system. In an alternative arrangement, bottom RDL 104 may be replaced with a PCB-based ground as a reflector for the slot bow-tie antenna. The top RDL 103 is deposited in a manner that forms a slot bow-tie antenna 105 and transmission line structure 106. The embedded silicon die 102 is used as the antenna substrate.

Semiconductor package 101 provides system-in-package (SiP) embedded die technology with antenna-on-package integration, which enables unique package-top-radiated AOP structure with direct air radiation patterns. Arrangements disclosed herein present an optimized slot bow-tie antenna operating in the 140-220 GHz (WR5) frequency band with direct air radiation and substrate-enhanced gain using SiP embedded die technology.

FIG. 2 is a detailed illustration of transmission line structure 106 coupled to semiconductor die 102. Transmission line structure 106 is a coplanar waveguide having a ground-signal-ground configuration. A middle conductive strip 201 is located between two ground strips 202, 203. The impedance of transmission line structure 106 depends on the width of feed strip 201 and the spacing between feed strip 201 and ground strips 202, 203. In one arrangement, transmission line structure 106 has a nominal impedance of 50Ω. The strips 201-203 of transmission line structure 106 are bonded to conductive pads 204-206 on the active surface of semiconductor die 102, which allows semiconductor die 102 to transmit and receive signals via transmission line structure 106. Conductive pads 205 and 206 are coupled to each other in some arrangements to ensure a consistent ground reference voltage to strips 202, 203. The coplanar waveguide arrangement shown in FIG. 2 has the advantage of low signal dispersion and broadband performance. The transmission line structure 106 in semiconductor package 101 only requires etching of top RDL 103, which allows for simple realization of the design.

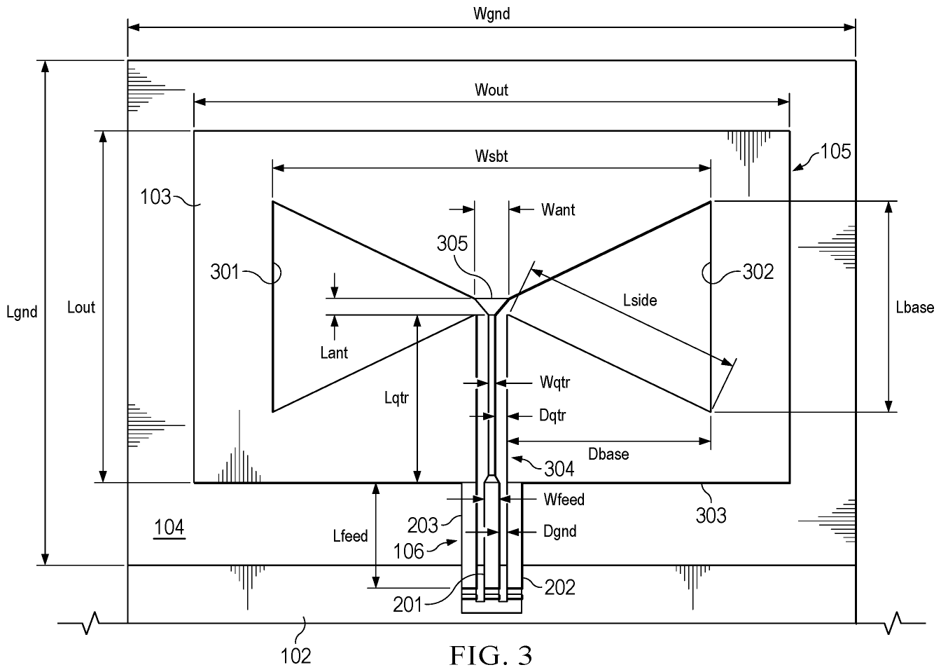

FIG. 3 illustrates a slot bow-tie antenna 105 used in a SiP configuration according to one arrangement. The integration of slot bow-tie antenna 105 in RDL 103 of semiconductor package 101 uses the substrate height encasing semiconductor die 102 to provide separate from ground RDL 104. A larger package size (i.e., larger than the footprint of semiconductor die 102) is required to accommodate antenna 105. Semiconductor package 101 also provides additional space to route signal I/Os and power. The ground-to-antenna separation is tuned to achieve the desired antenna performance with a starting value below quarter wavelength. The antenna 105 can be modified to work in either higher or lower frequency bands. In one arrangement, the ground reflector at RDL 104 is 155 um below antenna RDL 103. Slot bow-tie antenna 105 in RDL 103 is adjacent to the package top for maximum antenna efficiency and provides direct air radiation.

In the illustrated configuration, ground RDL 104 extends beyond one side of semiconductor die and has a width W_{gnd} and a length L_{gnd}. In one arrangement, W_{gnd} is 2000 um, and L_{gnd} is 1425 um. A substrate, which includes semiconductor die 102, separates ground RDL 104 from antenna RDL 103. The shape of the slot bow-tie antenna 105 is patterned as RDL 103 on the top surface of the substrate. The outside dimensions of slot bow-tie antenna 105 are a generally rectangular shape having width Wout and length Lout. In one arrangement, Wout is 1625 um, and Lout is 1000 um. Antenna 105 has two mirror-image triangular openings or slots 301, 302 that have a base of length L_{base} and two sides of length L_{side}. The base of the slots 301, 302 is spaced a distance D_{base} away from the antenna feed channel. The openings 301, 302 have an isosceles, equilateral, or scalene triangular shape. In one arrangement, directed toward the 140-220 GHz frequency operating range (WR5), L_{base} is 600 um, L_{side} is 623.87 um, and D_{base} is 560 um.

Coplanar waveguide transmission line structure 106 connects semiconductor die 102 to slot bow-tie antenna structure 105. Feed strip 201 has a width W_{feed} and is spaced apart from ground strips 202, 203 by a distance D_{gnd}. The width of the ground strips 202, 203 may be the same as the width W_{feed} of the feed strip 201 or may be another width. Transmission line structure 106 has a length L_{feed} between semiconductor die 102 and the edge 303 of antenna structure 105. A quarter-wave transformer 304 is used to compensate for impedance requirements at antenna feed 305. For example, the quarter-wave transformer may have an impedance of 75Ω. The quarter-wave transformer 304 includes a strip of width W_{qtr} that is spaced apart from slot bow-tie antenna structure 105 by a distance D_{qtr}. Quarter-wave transformer 304 has a length L_{qtr}. The antenna feed 305 has a width Wₐₙₜ at its widest point of attachment to slot bow-tie antenna structure 105 and has a length of Lₐₙₜ. In one arrangement, W_{feed} is 40 um, D_{feed} is 20 um, W_{qtr} is 20 um, D_{qtr} is 30 um, and L_{qtr} is 475 um. Antenna feed 305 may have dimensions Wₐₙₜ of 100 um and Lₐₙₜ of 50 um.

The slot bow-tie antenna is known to yield wide bandwidth and high efficiency. The linearly-polarized antenna radiation along the slot bow-tie antenna width is generated by exciting the two respective apertures 301, 302. The resonant frequency of the slot bow-tie antenna 105 may be adjusted by changing the width W_{sbt}. For example, increasing slot bow-tie width W_{sbt} increases the slot resonant length resulting in a longer current path and a lower resonant frequency. The length of the aperture base L_{base} can be tuned to input matching to a desired frequency.

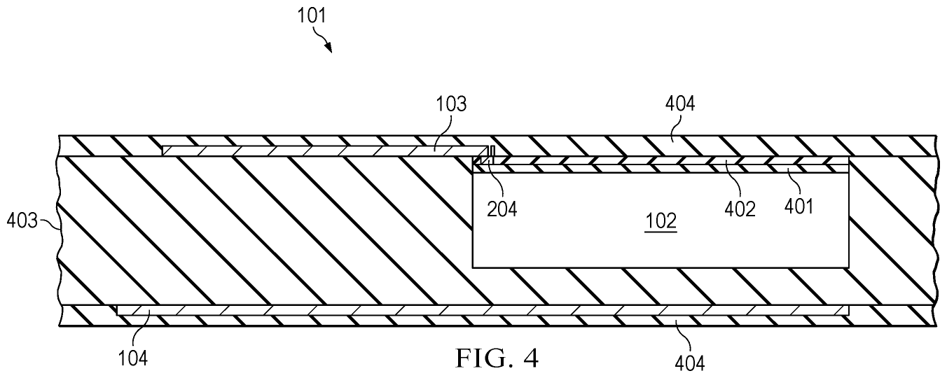

FIG. 4 is a cross section view along the length of semiconductor package 101. FIG. 4 illustrates semiconductor die 102 embedded between RDL layers 103 and 104, which form the antenna structure and ground, respectively. A passivation layer 401, such as silicon dioxide (SiO2) or aluminum oxide (Al2O3), may be applied to the surface of semiconductor die 102. A polyimide layer 402 may be attached to the passivation layer 401 below RDL 103. Conductive pad 204 provides a connection between semiconductor die 102 and RDL 103. Semiconductor die 102 is embedded in a filling material 403, such as an Ajinomoto build-up film (ABF) comprising an epoxy resin, between RDL 103 and 104. A solder mask 404 may be applied to the top and bottom surfaces of semiconductor package 101 for protection against oxidation and to prevent solder bridges from forming between closely spaced components.

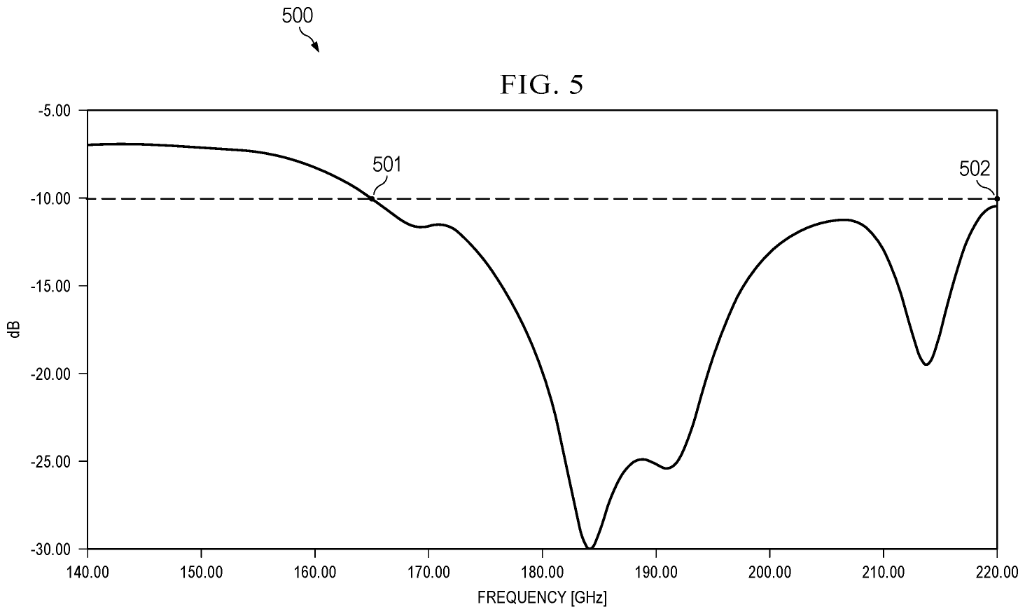

FIG. 5 is a graph 500 illustrating a return loss plot for an antenna-on-package device for a slot bow-tie antenna having the example dimensions listed above. A bandwidth of approximately 55 GHz has been observed in the WR5 frequency band using the example parameters wherein the return loss was below −10 dB between approximately 165 GHz (501) and 220 GHz (502).

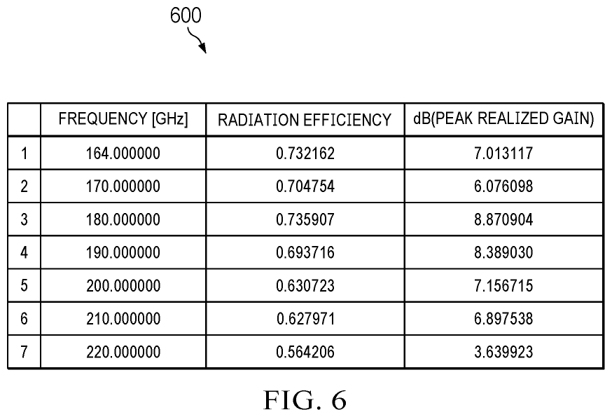

FIG. 6 is a table 600 listing gain and efficiency measurements for a slot bow-tie antenna having the example dimensions listed above. A maximum realized gain observed is approximately 8.87 dBi at 180 GHz with a maximum radiation efficiency of 73.5%. Overall, the peak realized gain observed is above 6 dBi in the WR5 frequency band with minimum radiation efficiency of 56%.

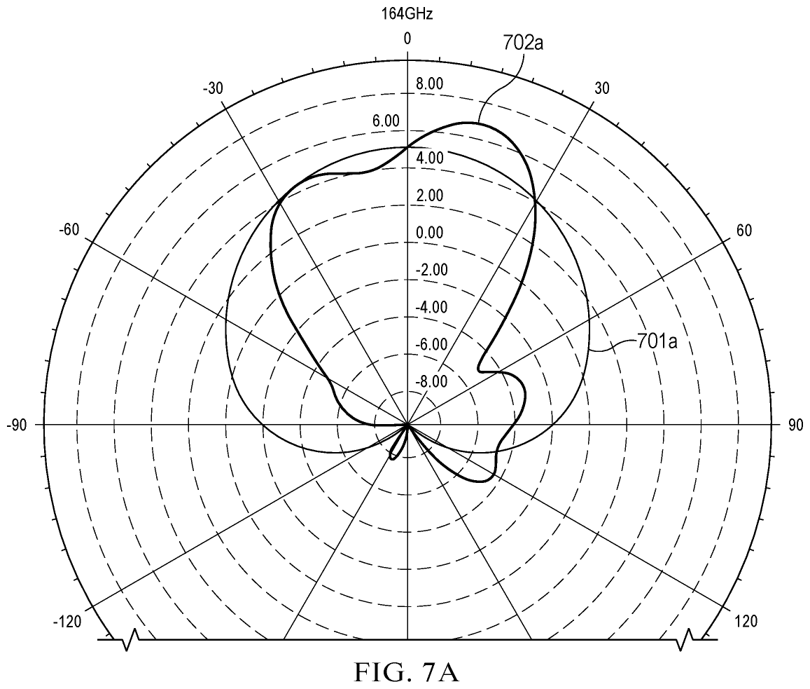

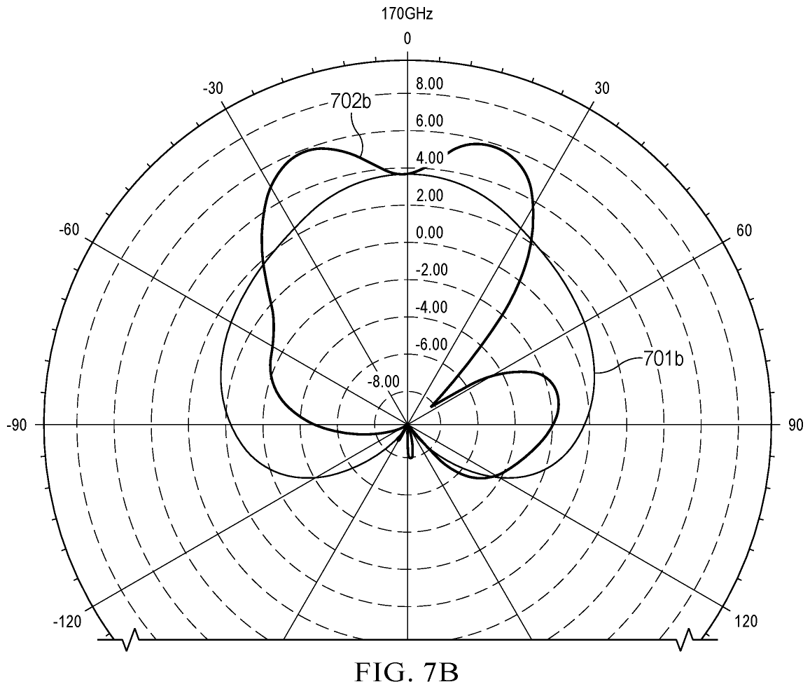

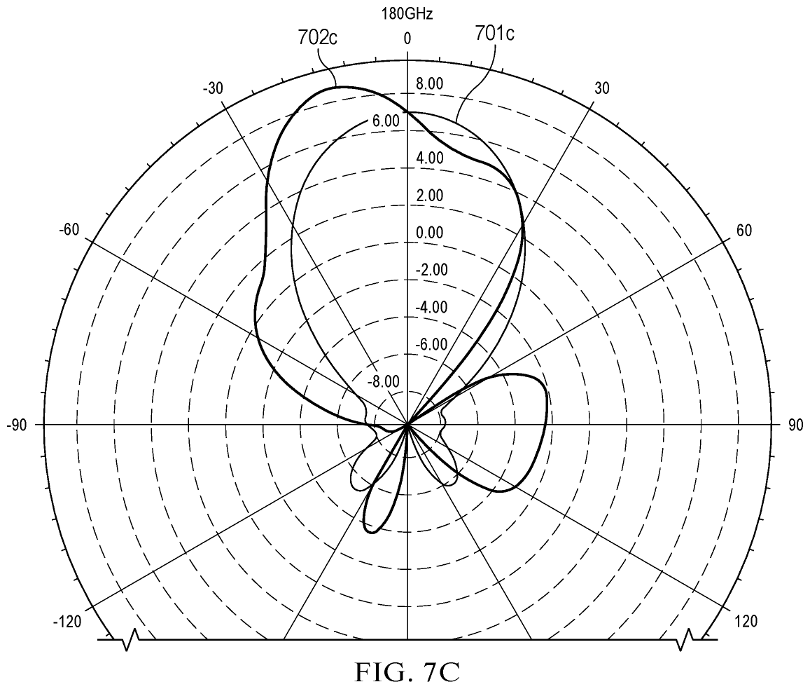

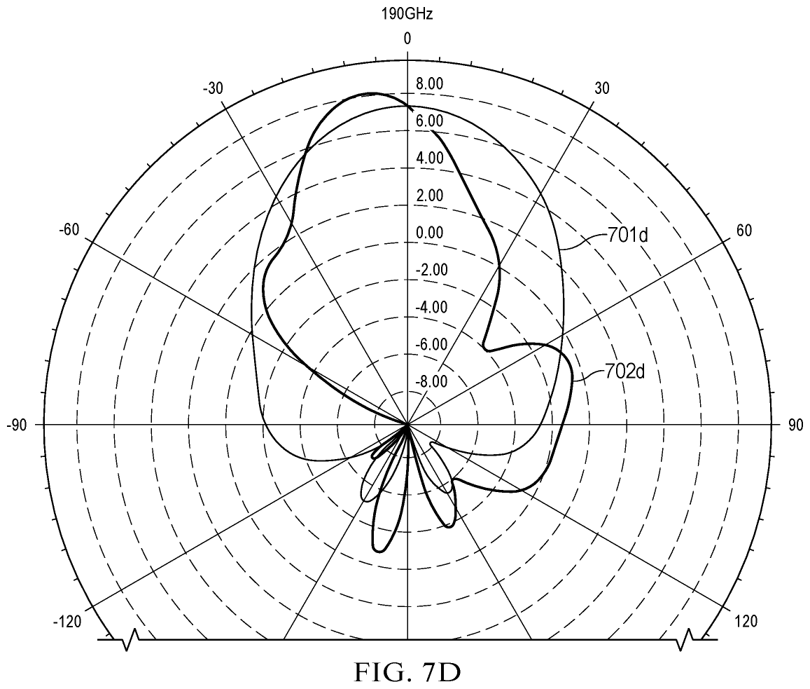

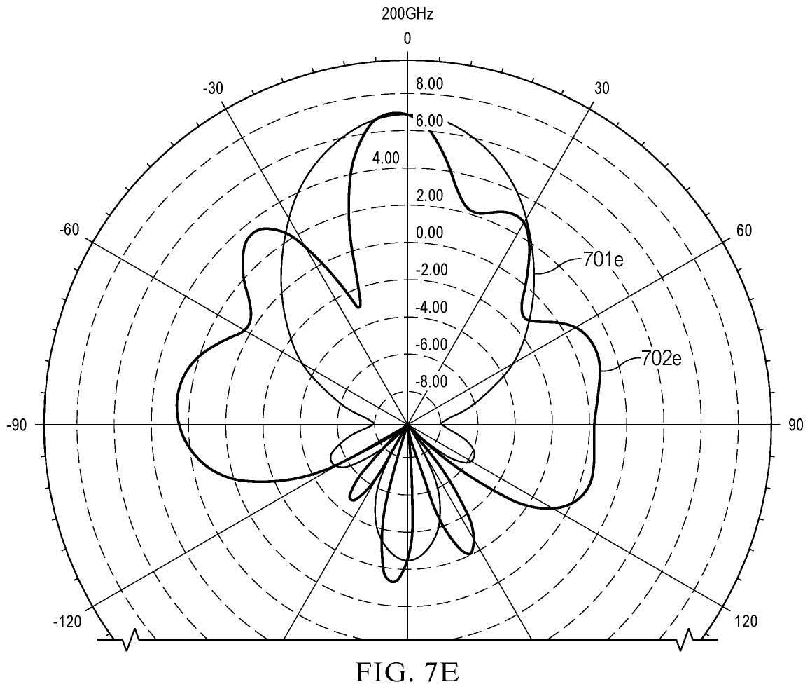

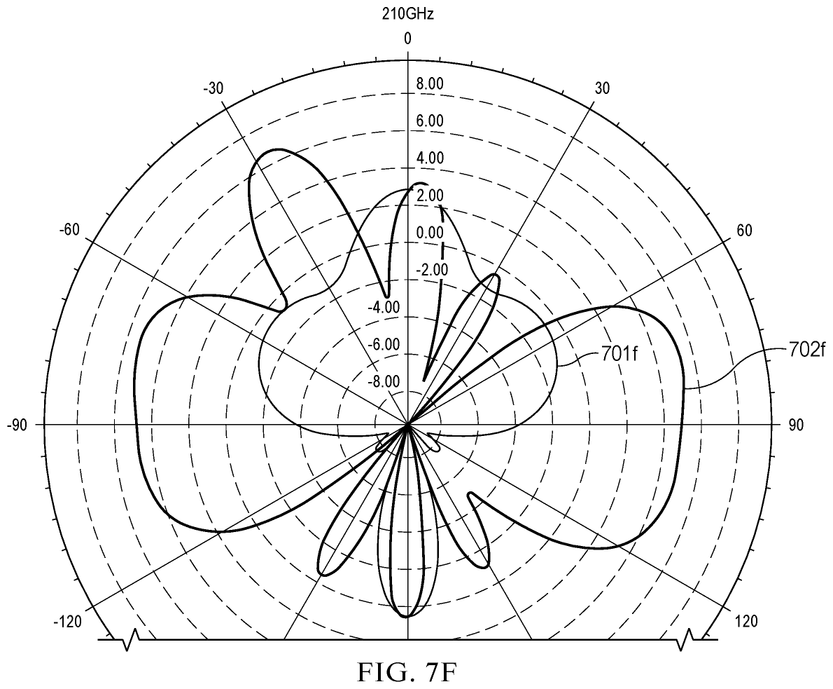

FIGS. 7A-F illustrate radiation patterns observed for an antenna-on-package device having a slot bow-tie antenna. Good radiation patterns are achieved across the frequency bandwidth 160-200 GHz. The best radiations are observed in the 180-200 GHz frequency range (FIGS. 7C-E). The radiations patterns are scattered at frequencies above 210 GHz due to the antenna size being too large in the illustrated example.

In FIG. 7A, plots 701a and 702a illustrate the radiation patterns at 164 GHz. Plot 701a represents the x-y or azimuth plane (i.e., φ=0 degrees). Plot 702a represents the y-z or elevation plane (i.e., φ=90 degrees). In FIG. 7B, plots 701b and 702b illustrate the radiation patterns at 170 GHz. Plot 701b represents the radiation pattern at φ=0 degrees. Plot 702b represents the radiation pattern at φ=90 degrees. In FIG. 7C, plots 701c and 702c illustrate the radiation patterns at 180 GHz. Plot 701c represents the radiation pattern at φ=0 degrees. Plot 702c represents the radiation pattern at φ=90 degrees.

In FIG. 7D, plots 701d and 702d illustrate the radiation patterns at 190 GHz. Plot 701d represents the radiation pattern at φ=0 degrees. Plot 702d represents the radiation pattern at φ=90 degrees. In FIG. 7E, plots 701e and 702e illustrate the radiation patterns at 200 GHz. Plot 701e represents the radiation pattern at φ=0 degrees. Plot 702e represents the radiation pattern at φ=90 degrees. In FIG. 7F, plots 701f and 702f illustrate the radiation patterns at 210 GHz. Plot 701f represents the radiation pattern at φ=0 degrees. Plot 702f represents the radiation pattern at φ=90 degrees.

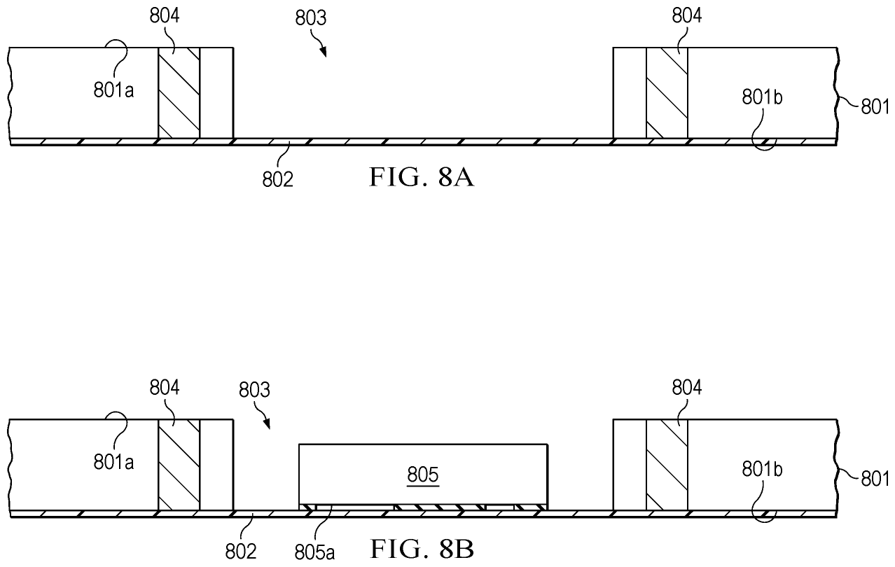

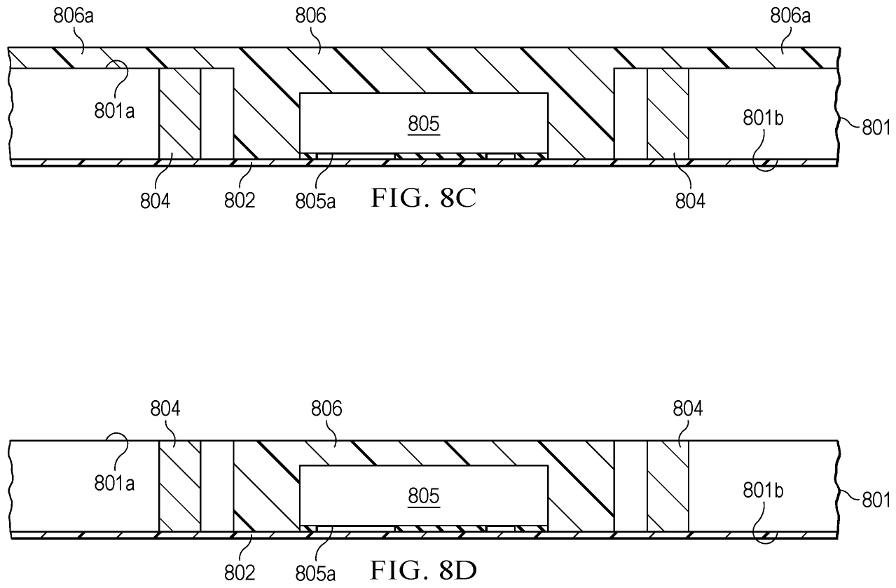

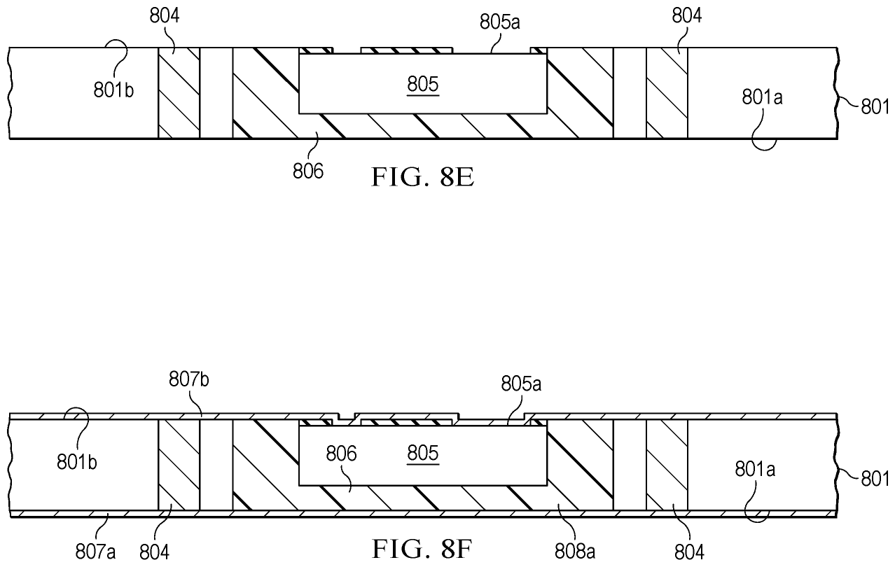

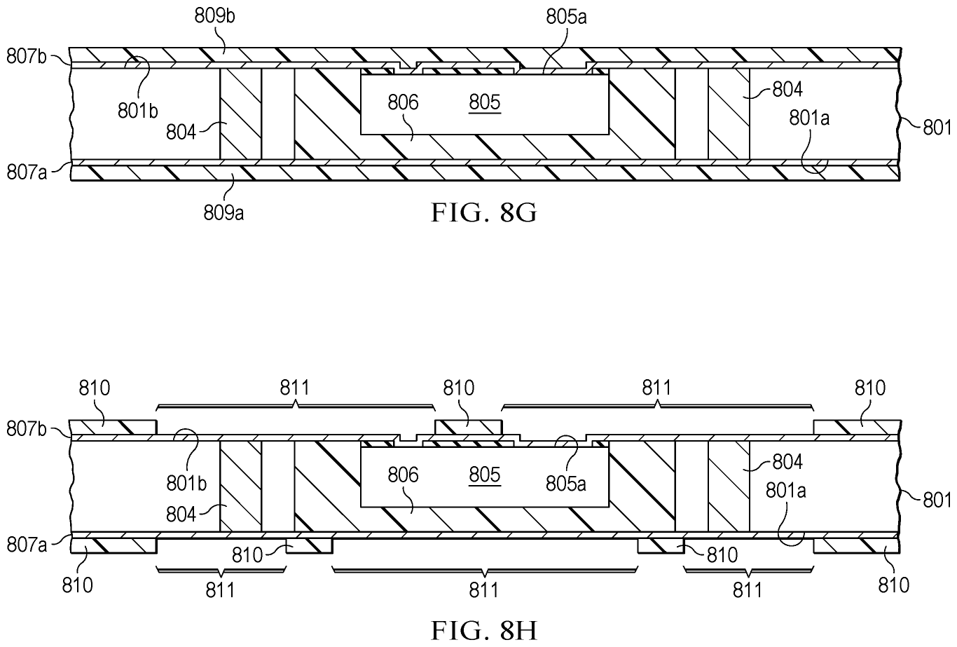

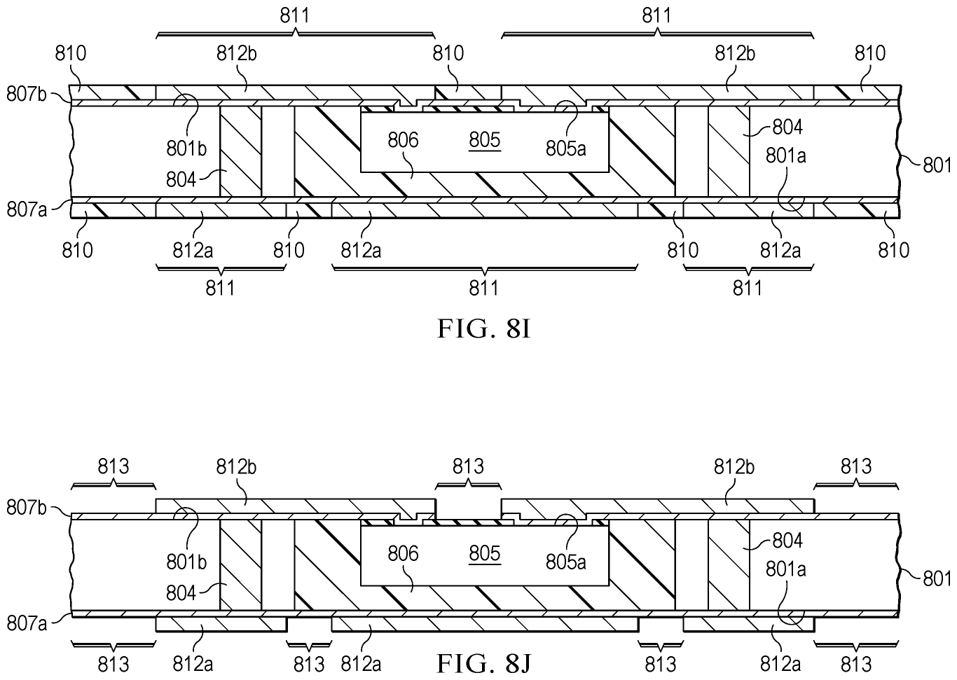

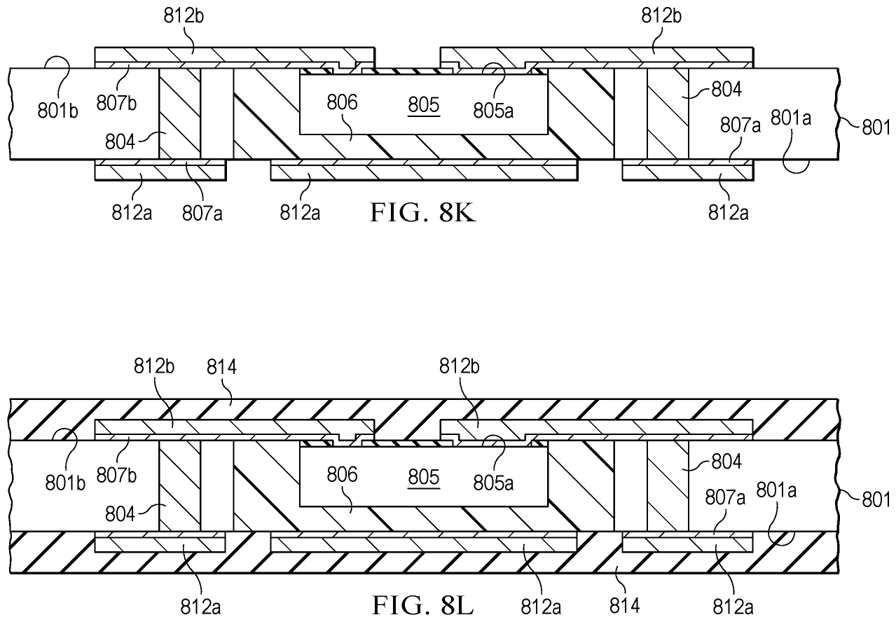

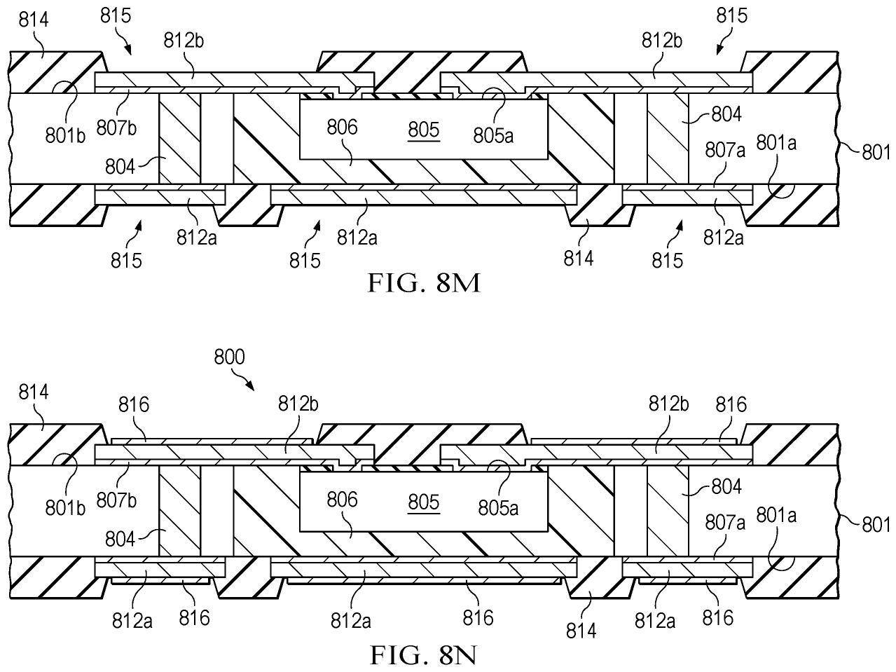

FIGS. 8A-N illustrate steps for fabricating a semiconductor package for an antenna-on-package device having a slot bow-tie antenna according to one arrangement. These steps can be used in one implementation to fabricate the device 101 described above. The steps may be used to concurrently fabricate multiple packaged electronic devices in a panelized batch process, with individual packaged electronic devices being separated after or near the end of the process.

In FIG. 8A, an organic panel frame 801 is attached to an adhesive carrier structure 802 (referred to as tacky tape). The panel frame 801 has a cavity 803 for mounting semiconductor dies or other components. In one example, the organic panel frame 801 is pressed onto an adhesive side of the adhesive carrier structure 802. In the illustrated arrangement, semiconductor die 805 has an active side 805a that is attached to the adhesive carrier structure 802. The organic panel frame 801 may have one or more conductive vias or plated through holes (PTH) 804, which allow for leads or other connections to be made between opposite sides of organic panel frame 801. The conductive vias or PTH 804 may be formed using one or more processing steps to electroplate copper in openings (not shown) formed through the panel frame 801. The conductive vias 804 extend from the first side 801a to the second side 801b of the panel frame 801.

In FIG. 8B, one or more semiconductor dies 805 are attached to the adhesive carrier structure 802 in cavity 803 of the organic panel frame 801. Semiconductor die 805 may be placed by a mechanized process (e.g., a pick and place process) that attaches the semiconductor die 805 to the adhesive carrier structure 802.

In FIG. 8C, a filling material 806 is formed in gaps between the organic panel frame 801 and the semiconductor die 805. The filling material 806 is created by forming buildup material in the gaps. The build-up material, such as ABF, in one example begins as sheets, and the fabrication process includes pressing or otherwise installing one or more sheets of the material into the gaps between the organic panel frame 801 and the semiconductor die 805 in cavity 803. The filling material 806 is then cured. Excess filling material 806a may cover the top surface 801a of organic panel frame 801, such as due to over molding of filling material 806.

In FIG. 8D, plasma etching is used to remove the excess filling material 806a and to expose the first side 801a of the organic panel frame 801.

In FIG. 8E, the structure has been flipped over so that the second side 801b of the panel frame 801 is on top. The adhesive carrier structure 802 has also been removed, which exposes the active side 805a of semiconductor die 805.

In FIG. 8F, a sputter deposition process is performed to deposit a copper seed layer 807a on the first side 801a of the organic panel frame 801 and to deposit a copper seed layer 807b on the second side 801b of the organic panel frame 801. The copper seed layer 807a also covers surface 808a of the filling material 806. The copper seed layer 807b also covers the active side 805a of semiconductor die 805 as well as the exposed surface 808b of the filling material 806.

In FIG. 8G, dry film (DF) photoresist layers 809a, 809b are laminated over the copper seed layers 807a, 807b.

In FIG. 8H, the photoresist layers 809a, 809b are exposed and developed. This patterns the photoresist material to form segments 810 of the resist on the top and bottom of the structure. Portions of the seed layers 807a, 807b are exposed when the photoresist layers 809a, 809b are developed.

In FIG. 8I, a conductive plating is deposited on both surfaces of the structure to form RDL layers 812a, 812b. In one arrangement, the RDL layers 812a, 812b may be formed using copper in an electroplating process that deposits a conductive copper material over the exposed portions of the copper seed layer 811 within the openings of the patterned resist 810. Although not shown in the cross-section view of FIG. 8I, RDL layer 812a may be formed in the shape of a ground layer and RDL layer 812b may be formed in the shape of a slotted bow-tie antenna in one arrangement.

In FIG. 8J, the remaining segments 810 of the DF photoresist layer removed, which exposes portions 813 of the underlying seed layer material 807a, 807b.

In FIG. 8K, the exposed portions 813 of the underlying seed layer material 807a, 807b have been etched away. This leaves the plated copper structures 812a, 812b that extend on or over select portions of the first and second sides of the structure.

In FIG. 8L, a solder mask 814 is applied to the top and bottom sides of the structure.

In FIG. 8M, pad openings 815 are created in the solder mask 814 to expose portions of RDL layers 812a, 812b.

In FIG. 8N, a thin film metal layer 816 is applied to the exposed portions of RDL layers 812a, 812b. The thin metal layer 816 may be under bump metallization (UBM) that may be used to support contacts to the semiconductor die 805 and other components of the structure.

Although the process shown in FIGS. 8A-N illustrates processing of both sides of the structure at the same time, it will be understood that in other arrangements one side may be processed first and then the structure flipped over and the other side processed.

FIG. 8N illustrates a system in package device 800 having a slot bow-tie antenna formed in RDL layer 812b according to one arrangement. Device 800 is a two-layer structure with RDL layers 812a, 812b.

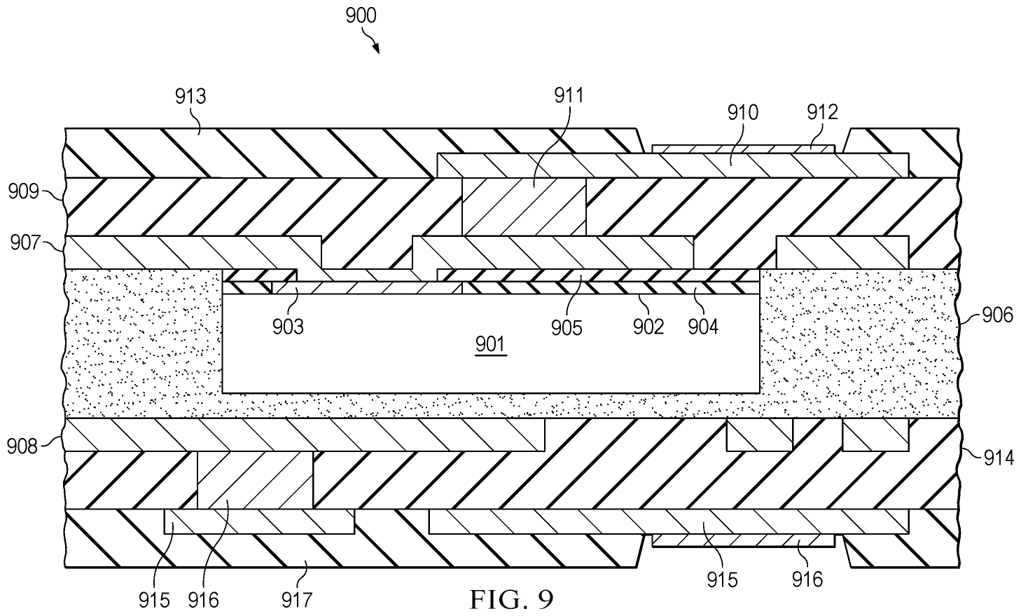

FIG. 9 illustrates a four-layer system in package device 900 having a slot bow-tie antenna formed in RDL layer 812b according to another arrangement. A semiconductor die 901 has an active surface 902 with one or more contact pads 903, such as a copper pad. A passivation layer 904 is formed over the active surface 902 but does not cover contact pad 903. A polyimide layer 905 is formed on top of the passivation layer 904. Semiconductor device 901 is embedded within a filling material 906, such as ABF or an epoxy resin. A first RDL layer 907 is formed on a top surface of the filling material 906 and is in contact with pad 903 on semiconductor device 901. RDL layer 907 may be formed in the shape of a slot bow-tie antenna in one configuration. A second RDL layer 908 is formed on a bottom surface of the filling material 906. In one arrangement, RDL 908 functions as a ground plane for an antenna structure formed in RDL 907.

An insulating dielectric layer 909 is formed on top of RLD 907. Dielectric layer 909 separates RDL 907 from conductive layer 910 that is formed on top of layer 909. Conductive layer 910 is electrically coupled to RDL 907 by one or more vias 911 that may be drilled through dielectric layer 909. A thin metal contact 912 is formed on conductive layer 910 and may function as an under bump material (UMB) for mounting contacts to external devices. A solder mask 913 or other protective material is deposited on dielectric layer 909 and conductive layer 910 so that only contact 912 is exposed on the top surface of device 900.

Similarly, insulating dielectric layer 914 is formed on the bottom of RLD 908. Dielectric layer 914 separates RDL 908 from a conductive layer 915 that is formed on the bottom of layer 914. Conductive layer 915 is electrically coupled to RDL 908 by one or more vias 916 that may be drilled through dielectric layer 914. A thin metal contact 916 is formed on conductive layer 915 and may function as an under bump material for mounting contacts to external devices. A solder mask 917 or other protective material is deposited on dielectric layer 914 and conductive layer 915 so that only contact 916 is exposed on the bottom surface of device 900.

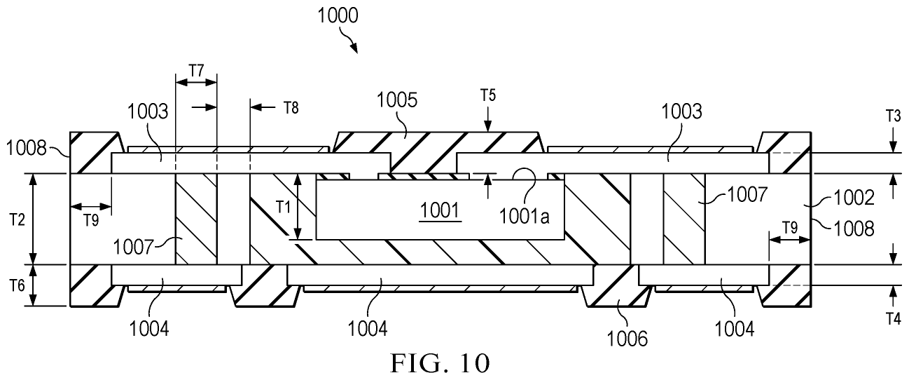

FIG. 10 is cross section view of an AOP device 1000 having a slot bow-tie antenna, such as a device manufactured using the process illustrated in FIGS. 8A-N, showing the thickness of various elements in one arrangement. Semiconductor die 1001 along with any passivation and polyimide layers on active surface 1001a has a thickness T1 of 65-150 um. Organic material 1002 has a thickness T2 of 100-180 um. Top RDL layer 1003 has a thickness T3 of 8-20 um, and bottom RDL layer 1004 similarly has a thickness T4 of 8-20 um. The top and bottom solder mask layers 1005, 1006 each have a thickness T5, T6 of 10-20 um.

The conductive vias or PTH 1007 have a width T7 of 105-150 um and are placed a distance T8 of 150-200 um away from the edge of semiconductor die 1001. The top and bottom RDL layers are spaced a distance T9 from the edges 1008 of package 1000.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a semiconductor die having a top surface;
a passivation layer over the top surface;
a first metal layer on the first passivation layer;
an antenna formed in the first metal layer and offset from the semiconductor die, the antenna having a slot bow-tie configuration;
a transmission line formed in the first metal layer, the transmission line coupling the semiconductor die to the antenna; and
an insulating material separating the first metal layer from a second metal layer, the second metal layer configured to function as a ground reflector for the antenna.

2. The semiconductor package of claim 1, further comprising:
a conductive pad on the top surface of the semiconductor die;
an opening in the passivation layer to expose the conductive pad;
the transmission line in the first metal layer in contact with the conductive pad through the first opening.

3. The semiconductor package of claim 1, wherein the transmission line is a coplanar waveguide.

4. The semiconductor package of claim 1, wherein the transmission line comprises three parallel strips in the first metal layer, and wherein the three parallel strips have a ground-signal-ground configuration.

5. The semiconductor package of claim 1, wherein the second metal layer extends below the antenna and the semiconductor die.

6. The semiconductor package of claim 1, wherein the antenna is configured to operate in a frequency band having a millimeter wavelength.

7. The semiconductor package of claim 1, wherein the antenna is configured in the first metal layer to provide direct air radiation.

8. The semiconductor package of claim 1, wherein the transmission line has a 50Ω impedance.

9. The semiconductor package of claim 1, further comprising
an impedance transformer formed in the first metal layer, wherein the impedance transformer is coupled between an antenna feed and the transmission line.

10. The semiconductor package of claim 9, wherein the impedance transformer has a 75Ω impedance.

11. The semiconductor package of claim 1, wherein the antenna comprises a metal plane having two triangular openings, the openings each having a vertex positioned near an antenna feed and a base side opposite the vertex, and wherein the distance between the base sides determines a resonant frequency of the antenna.

12. The semiconductor package of claim 1, further comprising:
a first dielectric layer covering the first metal layer;
a third metal layer covering the first dielectric layer; and
a first via in the first dielectric layer, the first via coupling the first metal layer to the third metal layer.

13. The semiconductor package of claim 12, further comprising:
a second dielectric layer covering the second metal layer;
a fourth metal layer covering the second dielectric layer; and
a second via in the second dielectric layer, the second via coupling the second metal layer to the fourth metal layer.

14. The semiconductor package of claim 1, further comprising:
a first solder mask layer above the first metal layer; and
a second solder mask layer below the second metal layer.

15. An integrated circuit (IC), comprising:
an embedded die structure, including:
an organic panel frame, including an opening,
a semiconductor die positioned within the opening;
a filling material that embeds the semiconductor die in the opening of the organic panel frame;
a first redistribution layer (RDL) structure positioned above the semiconductor die and having a conductive structure electrically connected to a contact on the semiconductor die;
an antenna formed in the first RDL structure and offset from the semiconductor die, the antenna having a slot bow-tie configuration; and
a second RDL structure positioned below the semiconductor die as a ground reflector for the antenna.

16. The IC of claim 15, further comprising:
a transmission line formed in the first RDL structure, the transmission line coupling the semiconductor die to the antenna.

17. The IC of claim 15, further comprising:
a waveguide in the first RDL structure, the waveguide having three parallel strips in the first metal layer, and wherein the three parallel strips have a ground-signal-ground configuration.

18. The IC of claim 15, wherein the second RDL structure extends below the antenna and the semiconductor die, wherein the antenna is configured to operate in a frequency band having a millimeter wavelength, and wherein the antenna is configured in the first RDL structure to provide direct air radiation.

19. The IC of claim 15, further comprising:
an impedance transformer formed in the first RDL structure, wherein the impedance transformer is coupled between an antenna feed and the transmission line;
wherein the transmission line has a 50Ω impedance; and
wherein the impedance transformer has a 75Ω impedance.

20. The IC of claim 15, further comprising:
a first dielectric layer covering the first RDL structure;
a third RDL structure covering the first dielectric layer;
a first via in the first dielectric layer, the first via coupling the first RDL structure to the third RDL structure;
a second dielectric layer covering the second RDL structure;
a fourth RDL structure covering the second RDL structure; and
a second via in the second dielectric layer, the second via coupling the second RDL structure to the fourth RDL structure.
